(19) United States
(12) Patent Application Publication
(10) Pub. No.: US 2016/0118514 A1
(43) Pub. Date: Apr. 28, 2016

(54) SOLAR CELL, SOLAR CELL PANEL, AND SOLAR CELL FILM

(71) Applicant: KABUSHIKI KAISHA TOSHIBA, Tokyo (JP)

(72) Inventor: Yongfang LI, Kawasaki (JP)

(21) Appl. No.: 14/920,258

(22) Filed: Oct. 22, 2015

(30) Foreign Application Priority Data
Oct. 28, 2014 (JP) 2014-219330

(51) Int. Cl. H01L 31/0224; H01L 31/0216; H01L 31/056; H01L 31/0352

(52) U.S. Cl. CPC H01L 31/022425; H01L 31/035272; H01L 31/02168; H01L 31/056

(57) ABSTRACT

According to one embodiment, a solar cell includes a first electrode, a photoelectric conversion film, a second electrode, and a first electret. The photoelectric conversion film is provided on the first electrode. The photoelectric conversion film includes a first semiconductor layer and a second semiconductor layer. The first semiconductor layer is of a first conductivity type. The second semiconductor layer is of a second conductivity type and provided on the first semiconductor layer. The first semiconductor layer and the second semiconductor layer generate a built-in electric field. The second electrode is provided on the photoelectric conversion film. The first electret is arranged with the photoelectric conversion film in a stacking direction of the first semiconductor layer and the second semiconductor layer. The first electret generates an external electric field. The external electric field and the built-in electric field are oriented toward the same side.

### CROSS-REFERENCE TO RELATED APPLICATIONS

This application is based upon and claims the benefit of priority from Japanese Patent Application No. 2014-219330, filed on Oct. 28, 2014; the entire contents of which are incorporated herein by reference.

### FIELD

Embodiments described herein relate generally to a solar cell, a solar cell panel, and a solar cell film.

### BACKGROUND

A solar cell performs photoelectric conversion to convert light such as sunlight or the like into electrical energy. For example, solar cells are utilized in a solar cell panel in which multiple solar cells are connected, or in a solar cell film that is flexible. It is desirable to increase the conversion efficiency of the photoelectric conversion of the solar cell.

### BRIEF DESCRIPTION OF THE DRAWINGS

FIGS. 1A and 1B are schematic views showing a solar cell according to a first embodiment;

FIGS. 2A to 2E are cross-sectional views schematically showing manufacturing processes of the solar cell according to the first embodiment;

FIGS. 3A and 3B are cross-sectional views schematically showing solar cells according to a second embodiment;

FIGS. 4A to 4C are cross-sectional views schematically showing solar cells according to a third embodiment;

FIG. 5 is a cross-sectional view schematically showing a solar cell according to a fourth embodiment;

FIG. 6 is a cross-sectional view schematically showing a solar cell according to a fifth embodiment;

FIG. 7A to FIG. 7C are cross-sectional views schematically showing solar cells according to a sixth embodiment;

FIG. 8 is a cross-sectional view schematically showing a solar cell film according to a seventh embodiment; and

FIG. 9 is a plan view schematically showing a solar cell panel according to an eighth embodiment.

### DETAILED DESCRIPTION

According to one embodiment, a solar cell includes a first electrode, a photoelectric conversion film, a second electrode, and a first electret. The photoelectric conversion film is provided on the first electrode. The photoelectric conversion film includes a first semiconductor layer and a second semiconductor layer. The first semiconductor layer is of a first conductivity type. The second semiconductor layer is of a second conductivity type and provided on the first semiconductor layer. The first semiconductor layer and the second semiconductor layer generate a built-in electric field. The second electrode is provided on the photoelectric conversion film. The first electret is arranged with the photoelectric conversion film in a stacking direction of the first semiconductor layer and the second semiconductor layer. The first electret generates an external electric field. The external electric field and the built-in electric field are oriented toward the same side.

According to another embodiment, a solar cell panel includes a substrate and a plurality of solar cells. The solar cells are electrically connected to each other and are arranged on the substrate. Each of the solar cells includes a first electrode, a photoelectric conversion film, a second electrode, and a first electret. The photoelectric conversion film is provided on the first electrode. The photoelectric conversion film includes a first semiconductor layer and a second semiconductor layer. The first semiconductor layer is of a first conductivity type. The second semiconductor layer is of a second conductivity type and provided on the first semiconductor layer. The first semiconductor layer and the second semiconductor layer generate a built-in electric field. The second electrode is provided on the photoelectric conversion film. The first electret is arranged with the photoelectric conversion film in a stacking direction of the first semiconductor layer and the second semiconductor layer. The first electret generates an external electric field. The external electric field and the built-in electric field are oriented toward the same side.

According to another embodiment, a solar cell film includes a substrate and a solar cell. The substrate is flexible. The solar cell is provided on the substrate. The solar cell includes a first electrode, a photoelectric conversion film, a second electrode, and a first electret. The photoelectric conversion film is provided on the first electrode. The photoelectric conversion film includes a first semiconductor layer and a second semiconductor layer. The first semiconductor layer is of a first conductivity type. The second semiconductor layer is of a second conductivity type and provided on the first semiconductor layer. The first semiconductor layer and the second semiconductor layer generate a built-in electric field. The second electrode is provided on the photoelectric conversion film. The first electret is arranged with the photoelectric conversion film in a stacking direction of the first semiconductor layer and the second semiconductor layer. The first electret generates an external electric field. The external electric field and the built-in electric field are oriented toward the same side.

Various embodiments will be described hereinafter with reference to the accompanying drawings.

The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

In the drawings and the specification of the application, components similar to those described in regard to a drawing thereinabove are marked with like reference numerals, and a detailed description is omitted as appropriate.

### First Embodiment

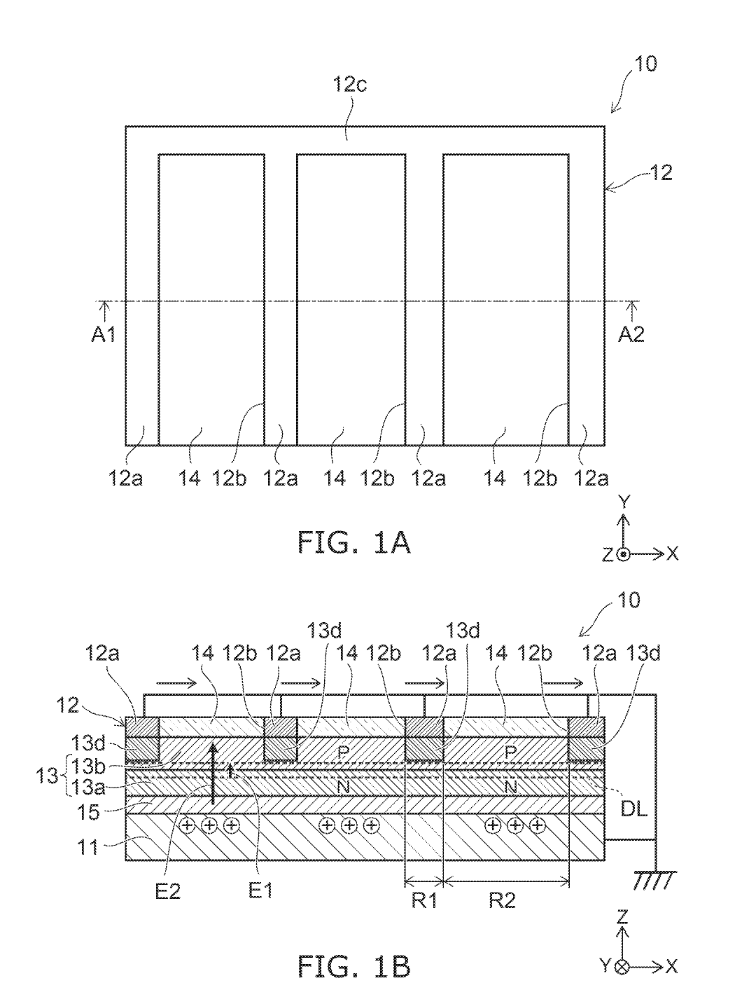

FIG. 1A and FIG. 1B are schematic views showing a solar cell according to a first embodiment.

FIG. 1A is a schematic plan view of the solar cell 10; and FIG. 1B is a schematic cross-sectional view of the solar cell 10. FIG. 1B schematically shows a line A1-A2 cross section of FIG. 1A.

As shown in FIG. 1A and FIG. 1B, the solar cell 10 includes a first electrode 11, a second electrode 12, a photoelectric conversion film 13, and an electret 14 (a first electret).

The photoelectric conversion film 13 is provided on the first electrode 11. The photoelectric conversion film 13 includes a first semiconductor layer 13a and a second semiconductor layer 13b. The first semiconductor layer 13a is provided on the first electrode 11. The second semiconductor layer 13b is provided on the first semiconductor layer 13a.

Here, the stacking direction of the first semiconductor layer 13a and the second semiconductor layer 13b is taken as a Z-axis direction. One direction perpendicular to the Z-axis direction is taken as an X-axis direction. A direction perpendicular to the X-axis direction and the Z-axis direction is taken as a Y-axis direction.

The first semiconductor layer 13a is of a first conductivity type. The second semiconductor layer 13b is of a second conductivity type. For example, the first conductivity type is an n-type; and the second conductivity type is a p-type. The first conductivity type may be the p-type; and the second conductivity type may be the n-type. Hereinbelow, the case is described where the first conductivity type is the n-type and the second conductivity type is the p-type. In other words, in the example, the first semiconductor layer 13a is an n-type semiconductor; and the second semiconductor layer 13b is a p-type semiconductor.

For example, the second semiconductor layer 13b contacts the first semiconductor layer 13a. For example, the second semiconductor layer 13b has a p-n junction with the first semiconductor layer 13a. A depletion layer DL is formed at the junction interface vicinity between the first semiconductor layer 13a and the second semiconductor layer 13b. The portion of the depletion layer DL in the first semiconductor layer 13a has a positive charge due to insufficient electrons which are the majority carriers. On the other hand, the portion of the depletion layer DL in the second semiconductor layer 13b has a negative charge due to insufficient holes which are the majority carriers. Thereby, the first semiconductor layer 13a and the second semiconductor layer 13b generate a built-in electric field E1 inside the depletion layer DL in the direction from the first semiconductor layer 13a toward the second semiconductor layer 13b.

The photoelectric conversion film 13 is Si-based, compound-based, organic material-based, etc. Si-based includes, for example, monocrystalline silicon, polycrystalline silicon, thin film polycrystalline silicon, etc. Compound-based includes, for example, CIGS (CuInGaSe₂), CdTe, semiconductor multi-junction, GaAs, InP, compound multi-junction, etc. The first semiconductor layer 13a and the second semiconductor layer 13b may include organic semiconductors. However, it is favorable for the photoelectric conversion film 13 to be compound-based or Si-based with good crystallinity.

The first electrode 11 is electrically connected to the first semiconductor layer 13a. In the example, the first electrode 11 is negative. The first electrode 11 is light-reflective. The first electrode 11 includes, for example, a metal material such as Al, Ag, Ti, etc. The material of the first electrode 11 may be any material that is conductive and light-reflective.

A conductive layer 15 is provided between the first electrode 11 and the photoelectric conversion film 13. For example, the conductive layer 15 contacts the first electrode 11 and the photoelectric conversion film 13. The first electrode 11 is electrically connected to the photoelectric conversion film 13 via the conductive layer 15.

The conductive layer 15 is, for example, a seed layer. The conductive layer 15 reduces the lattice constant difference between the first electrode 11 and the photoelectric conversion film 13. The difference between the lattice constant of the conductive layer 15 and the lattice constant of the photoelectric conversion film 13 is smaller than the difference between the lattice constant of the first electrode 11 and the lattice constant of the photoelectric conversion film 13. Thereby, for example, in the compound-based photoelectric conversion film 13 or the like, the crystal structure can be good; and the lifetime of the carriers excited by the sunlight can be lengthened. For example, the active current that is extracted can be increased. For example, the photoelectric conversion efficiency can be increased. The conductive layer 15 is provided as necessary and is omissible.

The second electrode 12 is provided on the photoelectric conversion film 13. In the example, the second electrode 12 is positive. In the case where the first semiconductor layer 13a is of the p-type and the second semiconductor layer 13b is of the n-type, the first electrode 11 is positive and the second electrode 12 is negative, which are the opposite of those recited above.

For example, the second electrode 12 contacts the photoelectric conversion film 13. Thereby, the second electrode 12 is electrically connected to the photoelectric conversion film 13. Another conductive layer may be provided between the second electrode 12 and the photoelectric conversion film 13.

The second electrode 12 includes multiple conductive units 12a, multiple openings 12b, and a connection unit 12c. The conductive units 12a extend in the Y-axis direction and are arranged in the X-axis direction. The openings 12b are provided respectively between the conductive units 12a. Each of the openings 12b exposes a portion of the photoelectric conversion film 13. The connection unit 12c is connected to one Y-axis direction end of each of the conductive units 12a and electrically connects the conductive units 12a. In other words, in the example, the second electrode 12 is a comb-shaped electrode. The second electrode 12 includes, for example, a metal material such as Al, Ag, Ti, etc. In the example, the second electrode 12 is light-reflective.

In the solar cell 10, light is incident on the photoelectric conversion film 13 through the openings 12b of the second electrode 12. Thereby, a voltage that corresponds to the amount of the light incident on the photoelectric conversion film 13 is generated between the first electrode 11 and the second electrode 12. A portion of the light that is incident on the photoelectric conversion film 13 passes through the photoelectric conversion film 13, is reflected by the first electrode 11, and again is incident on the photoelectric conversion film 13. Accordingly, the first electrode 11 includes a material having high light reflectivity. Thereby, the photoelectric conversion efficiency can be increased. In other words, the first electrode 11 is a reflecting electrode.

The configuration of the second electrode 12 is not limited to a comb-shaped configuration and may be, for example, a lattice configuration, etc. The configuration of the second electrode 12 may be, for example, any configuration that can cause the light to be incident on the photoelectric conversion film 13 and can obtain an appropriate electrical connection with the photoelectric conversion film 13. The second electrode 12 may be light-transmissive. The second electrode 12 may include a material that is light-transmissive such as ITO, etc. In such a case, the openings 12b are omissible. In the case where the second electrode 12 is light-transmissive, the second electrode 12 may be provided on the entire photoelectric conversion film 13.

The second semiconductor layer 13b includes a first region R1 and a second region R2, where the second electrode 12 and the first region R1 overlap in the Z-axis direction, and the second electrode 12 and the second region R2 do not overlap in the Z-axis direction. In other words, the first region R1 is a region such that the conductive units 12a and the first region R1 overlap in the Z-axis direction. In other words, the second region R2 is a region such that the openings 12b and the second region R2 overlap in the Z-axis direction.

A highly doped layer 13d is provided in the second semiconductor layer 13b under the second electrode 12. In other words, the highly doped layer 13d is provided in the upper portion of the first region R1. In the example, the highly doped layer 13d is a p⁺-layer. The highly doped layer 13d is the portion of the second semiconductor layer 13b in which the concentration of the impurity corresponding to the majority carrier is higher than that of other portions. Accordingly, the concentration of the impurity included in the first region R1 is higher than the concentration of the impurity included in the second region R2. Thereby, for example, the excited carriers can be extracted easily. For example, the photoelectric conversion efficiency can be increased.

The electret 14 is arranged with the photoelectric conversion film 13 in the Z-axis direction. In the example, the electret 14 is provided on the photoelectric conversion film 13.

The electret 14 is provided between the conductive units 12a. In other words, the electret 14 is provided on the portion of the photoelectric conversion film 13 exposed at the opening 12b. In the example, the electret 14 is light-transmissive. The electret 14 is, for example, transparent. In the solar cell 10, the light that passes through the electret 14 is incident on the photoelectric conversion film 13.

Multiple electrets 14 are provided in the example. The electrets 14 are provided respectively between the conductive units 12a. The number of electrets 14 may be one. For example, one electret 14 having a comb-shaped configuration may be provided.

The electrets 14 retain charge and are charged with a prescribed polarity. In the example, the polarity of the charge retained by the electrets 14 is the same as the polarity of the charge of the majority carrier of the first semiconductor layer 13a. In other words, the electrets 14 retain the same negative charge as electrons which are the majority carriers of the first semiconductor layer 13a. In other words, the electrets 14 are negatively charged.

Thereby, the electrets 14 generate an external electric field E2 in the direction from the first electrode 11 toward the electrets 14. In other words, the electrets 14 generate the external electric field E2; and the external electric field E2 and the built-in electric field E1 are oriented toward the same side.

It is sufficient for the direction in which the external electric field E2 is oriented to have at least a component in the same direction as the direction in which the built-in electric field E1 is oriented. The angle between the direction in which the built-in electric field E1 is oriented and the direction in which the external electric field E2 is oriented is less than 90°. However, it is favorable for the direction in which the external electric field E2 is oriented to be substantially the same as the direction in which the built-in electric field E1 is oriented.

For example, the electrets 14 include a so-called resin-based electret in which an insulative resin film is made into an electret by implanting electrons or ions produced by corona discharge into the resin film. Thereby, a negative charge can be retained in the electrets 14.

The electrets 14 include, for example, an amorphous fluorocarbon resin. The surface charge density of the electret 14 including the amorphous fluorocarbon resin is, for example, in the range of −0.2 mC/m² to −2.1 mC/m². Thus, the electret 14 that includes the amorphous fluorocarbon resin can obtain a high surface charge density. The electret 14 that includes the amorphous fluorocarbon resin can retain the surface charge density recited above for 4000 hours or more. For example, the electret 14 that includes the amorphous fluorocarbon resin can obtain good temperature stability in a range of about 100° C. or less. Thus, the electret 14 that includes the amorphous fluorocarbon resin has superior durability and temperature stability and can stably retain charge.

For example, the electrons or the ions produced by corona discharge are implanted into an amorphous fluorocarbon resin. At this time, the coating conditions of the resin and the implantation conditions of the ions of the corona discharge are controlled. Thereby, the film thickness of the amorphous fluorocarbon resin and the density of the charge retained in the amorphous fluorocarbon resin can be adjusted freely. Thus, the film thickness and the charge density can be adjusted freely for the electrets 14.

As a part of global warming prevention, it is desirable to reduce the emission amount of CO₂. Moreover, reserves of “exhaustible energy” that is commonly used today are limited; and it is said that reserves will be exhausted within about several tens of years to several hundreds of years. Therefore, “renewable energy” typified by photovoltaic power generation is drawing attention as an energy source that has a low likelihood of being exhausted, is environment-friendly, and is sufficiently practical.

It is desirable to increase the photoelectric conversion efficiency of solar cells. For example, a method in which the short circuit current is increased by providing an intrinsic semiconductor layer (a so-called i-layer) between a p-type layer and an n-type layer is known as a method for increasing the photoelectric conversion efficiency. However, the manufacturing cost increases as the thickness of the i-layer is increased. Moreover, when the depletion layer becomes too large, the electric field weakens; and the extraction efficiency of the carriers undesirably decreases.

The depletion layer also can be controlled by applying an external bias. In the case where a forward bias is applied, the built-in electric field weakens. Therefore, holes diffuse from the p-type layer into the n-type layer; electrons diffuse from the n-type layer into the p-type layer; and a diffusion current flows.

On the other hand, in the case where a reverse bias is applied, the built-in electric field inside the depletion layer is strengthened. The depletion layer spreads proportionally to the square root of the bias voltage. For example, at the p-n junction of the solar cell as well, the depletion layer can be widened by applying the reverse bias. In other words, the short circuit current is increased; and the photoelectric conversion efficiency can be increased. However, the application of the external bias is difficult to realize in solar cell applications because an external power supply is necessary.

Conversely, in the solar cell 10 according to the embodiment, the electret 14 is provided on the photoelectric conversion film 13; the electret 14 generates the external electric field E2; and the external electric field E2 and the built-in electric field E1 are oriented toward the same side. Thereby, in the solar cell 10 according to the embodiment, the depletion layer can be spread similarly to the case where the reverse bias is applied without providing the external power supply. Accordingly, in the solar cell 10 according to the embodiment, the photoelectric conversion efficiency can be increased.

A width xₙ of the depletion layer DL of the first semiconductor layer 13a (the n-type layer) in the case where the bias is not applied can be determined using the following Formula (1). A width xₚ of the depletion layer DL of the second semiconductor layer 13b (the p-type layer) in the case where the bias is not applied can be determined using the following Formula (2).

$$\begin{matrix}[ Formula 1 ] & \\ {x}_{n} = \sqrt{\frac{2 ɛ {N}_{a}}{{qN}_{d} ( {N}_{d} + {N}_{a} )} {φ}_{B}} & ( 1 ) \\ [ Formula 2 ] & \\ {x}_{p} = \sqrt{\frac{2 ɛ {N}_{d}}{{qN}_{a} ( {N}_{d} + {N}_{a} )} {ϕ}_{B}} & ( 2 )\end{matrix}$$

In Formula (1) and Formula (2), N_{d} is the impurity concentration of the first semiconductor layer 13a. Nₐ is the impurity concentration of the second semiconductor layer 13b. q is the unit charge (the elementary charge). ∈ is the dielectric constant of the photoelectric conversion film 13. Φ_{B} and φ_{B} are the magnitude of the built-in electric field E1.

On the other hand, a width Xₙ of the depletion layer DL of the first semiconductor layer 13a in the case where a bias V_{b} is applied can be determined using the following Formula (3). A width Xₚ of the depletion layer DL of the second semiconductor layer 13b in the case where the bias V_{b} is applied can be determined using the following Formula (4).

$$\begin{matrix}[ Formula 3 ] & \\ {X}_{n} = \sqrt{\frac{2 ɛ {N}_{a}}{{qN}_{d} ( {N}_{d} + {N}_{a} )} ( {φ}_{B} - {V}_{b} )} & ( 3 ) \\ [ Formula 4 ] & \\ {X}_{p} = \sqrt{\frac{2 ɛ {N}_{d}}{{qN}_{a} ( {N}_{d} + {N}_{a} )} ( {ϕ}_{B} - {V}_{b} )} & ( 4 )\end{matrix}$$

For example, the increase rate of the width of the depletion layer DL when the bias V_{b} is applied can be determined using the following Formula (5).

$$\begin{matrix}[ Formula 5 ] & \\ \begin{matrix}\frac{{x}_{n} + {x}_{p}}{{x}_{n} + {x}_{p}} = \frac{\sqrt{\frac{2 ɛ {N}_{a}}{{qN}_{d} ( {N}_{d} + {N}_{a} )} ( {φ}_{B} - {V}_{b} )} + \sqrt{\frac{2 ɛ {N}_{d}}{{qN}_{a} ( {N}_{d} + {N}_{a} )} ( {ϕ}_{B} - {V}_{b} )}}{\sqrt{\frac{2 ɛ {N}_{a}}{{qN}_{d} ( {N}_{d} + {N}_{a} )} {φ}_{B}} + \sqrt{\frac{2 ɛ {N}_{d}}{{qN}_{a} ( {N}_{d} + {N}_{a} )} {ϕ}_{B}}} \\ = \frac{\sqrt{\frac{2 ɛ ( {φ}_{B} - {V}_{b} )}{q ( {N}_{d} + {N}_{a} )}} \times ( \sqrt{\frac{{N}_{a}}{{N}_{d}}} + \sqrt{\frac{{N}_{d}}{{N}_{a}}} )}{\sqrt{\frac{2 ɛ {φ}_{B}}{q ( {N}_{d} + {N}_{a} )}} \times ( \sqrt{\frac{{N}_{a}}{{N}_{d}}} + \sqrt{\frac{{N}_{d}}{{N}_{a}}} )} \\ = \sqrt{\frac{{φ}_{B} - {V}_{b}}{{φ}_{B}}} \\ = \sqrt{1 - \frac{{V}_{b}}{{φ}_{B}}} \\ \approx \sqrt{{V}_{b}}\end{matrix} & ( 5 )\end{matrix}$$

In the case where the reverse bias is applied, V_{b} in Formula (5) is −V_{b}. Also, V_{b}>>Φ_{B}.

Thus, in the case where the reverse bias is applied to the photoelectric conversion film 13 having the p-n junction, the width of the depletion layer DL spreads proportionally to the square root of the bias voltage V_{b}. Accordingly, in the case where the reverse bias is applied, the photoelectric conversion efficiency of the solar cell increases proportionally to the square root of the bias voltage V_{b}.

In the solar cell 10 according to the embodiment, the amount of charge retained by the electrets 14 is increased. In other words, the external electric field E2 is increased. Thereby, in the solar cell 10 according to the embodiment, the photoelectric conversion efficiency can be increased.

In the embodiment recited above, the first semiconductor layer 13a and the second semiconductor layer 13b are used as the photoelectric conversion film 13 having the p-n junction. For example, the photoelectric conversion film 13 is not limited thereto; and a third semiconductor layer that has a lower concentration of the impurity than the first semiconductor layer 13a and the second semiconductor layer 13b may be further provided between the first semiconductor layer 13a and the second semiconductor layer 13b. For example, an intrinsic semiconductor layer may be provided between the first semiconductor layer 13a and the second semiconductor layer 13b. In other words, the photoelectric conversion film 13 may be a p-i-n junction.

Compared to the case of the p-n junction, the width of the depletion layer DL can be set to be wider in the case where the photoelectric conversion film 13 is the p-i-n junction. In other words, the photoelectric conversion efficiency can be increased further. On the other hand, in the case where the photoelectric conversion film 13 has the p-n junction, for example, the depletion layer DL becoming too large and the undesirable weakening of the built-in electric field E1 can be suppressed. Also, for example, the increase of the manufacturing cost due to providing the i-layer can be suppressed. For example, as in the solar cell 10 recited above, the photoelectric conversion film 13 has the p-n junction; and the electrets 14 are provided. Thereby, for example, the photoelectric conversion efficiency can be increased while suppressing the decrease of the built-in electric field E1 and the increase of the manufacturing cost.

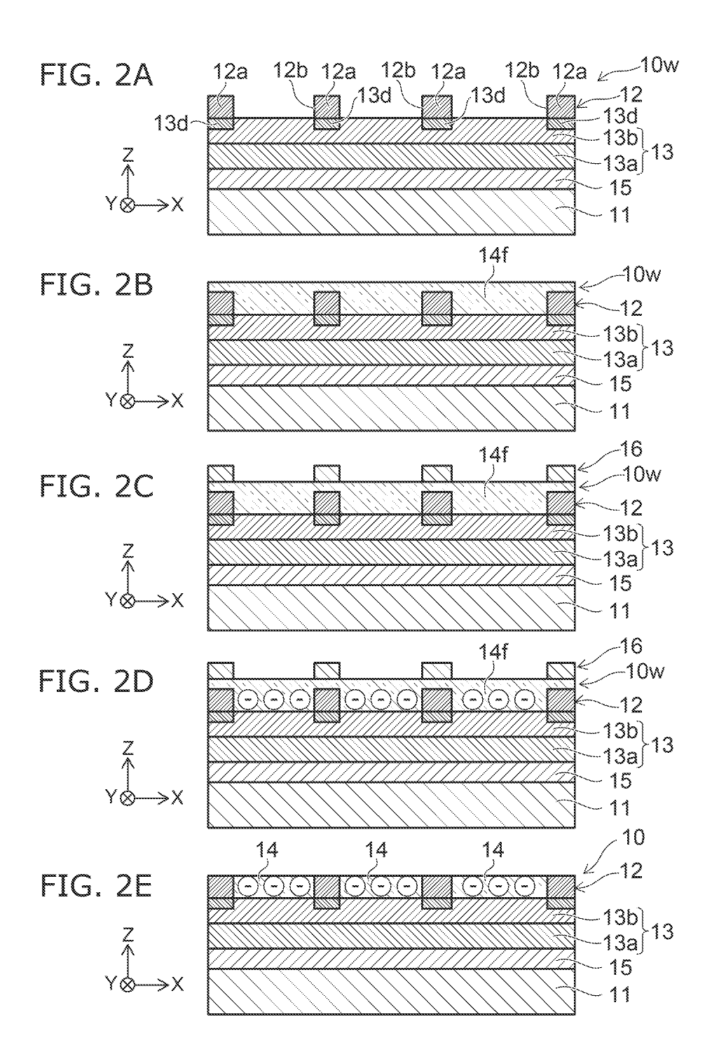

FIG. 2A to FIG. 2E are cross-sectional views schematically showing manufacturing processes of the solar cell according to the first embodiment.

In the manufacturing of the solar cell 10 as shown in FIG. 2A, first, a patterning body 10w is prepared. The patterning body 10w includes the first electrode 11, the second electrode 12, the photoelectric conversion film 13, and the conductive layer 15. As described above, the conductive layer 15 is provided as necessary and is omissible.

For example, in the case where the photoelectric conversion film 13 is compound-based, the first electrode 11, the conductive layer 15, the first semiconductor layer 13a, the second semiconductor layer 13b, and the second electrode 12 are formed in order on a not-shown substrate. For example, in the case where the photoelectric conversion film 13 is silicon-based, the conductive layer 15 and the first electrode 11 are formed on one surface of the semiconductor substrate; and the second electrode 12 is formed on the other surface of the semiconductor substrate. Thereby, the patterning body 10w is formed.

Thus, the process of preparing the patterning body 10w includes the process of forming the patterning body 10w. The process of preparing the patterning body 10w is not limited to forming the patterning body 10w and may be, for example, a process of setting a pre-formed patterning body 10w in a manufacturing apparatus, etc.

As shown in FIG. 2B, an insulating film 14f (a resin film) that is used to form the electrets 14 is formed on the patterning body 10w. The insulating film 14f includes, for example, an amorphous fluorocarbon resin. For example, a coating method such as spin coating or the like is used to form the insulating film 14f.

As shown in FIG. 2C, a resist film 16 that corresponds to the configuration of the second electrode 12 is formed on the insulating film 14f by a photolithography process.

As shown in FIG. 2D, for example, the insulating film 14f is made into an electret by implanting electrons or ions produced by corona discharge into the insulating film 14f from above the resist film 16.

As shown in FIG. 2E, the resist film 16 is removed; and the insulating film 14f is etched until the second electrode 12 is exposed. The etching of the insulating film 14f includes, for example, RIE (Reactive Ion Etching). Thereby, the electrets 14 are formed from the insulating film 14f; and the solar cell 10 is completed.

### Second Embodiment

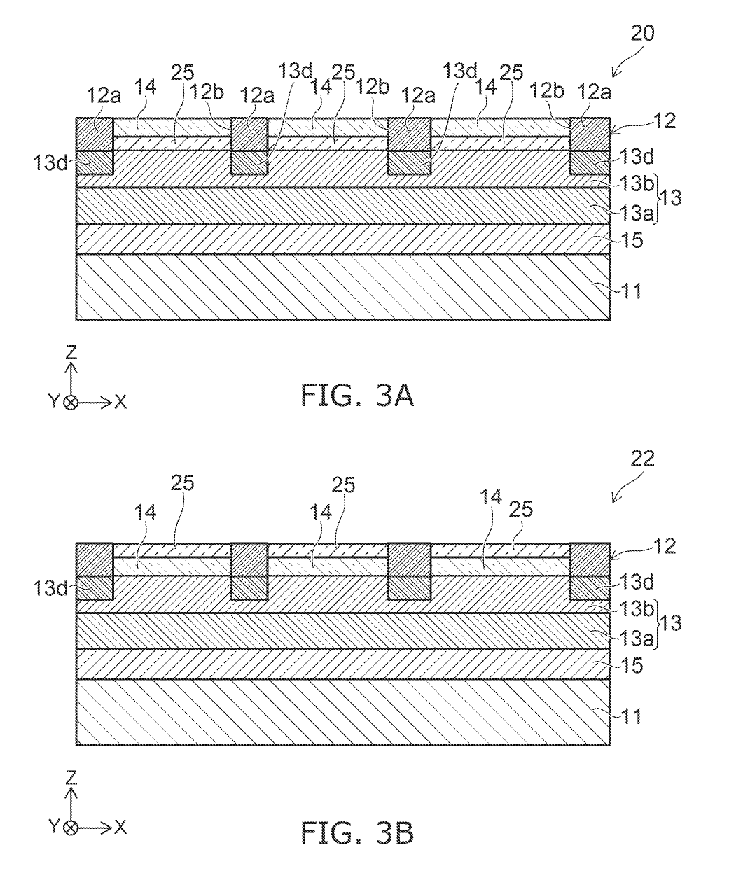

FIG. 3A and FIG. 3B are cross-sectional views schematically showing solar cells according to a second embodiment.

As shown in FIG. 3A, a solar cell 20 further includes an anti-reflection film 25. Components having substantially the same functions and configurations as those of the embodiment recited above are marked with like reference numerals, and a detailed description is omitted.

The anti-reflection film 25 is provided on the photoelectric conversion film 13. The anti-reflection film 25 is provided between the photoelectric conversion film 13 and the electrets 14. In the example, multiple anti-reflection films 25 are provided between the photoelectric conversion film 13 and the electrets 14.

The anti-reflection film 25 suppresses reflection of the light that is incident on the photoelectric conversion film 13. The anti-reflection film 25 may utilize a difference of refractive indexes, may utilize a micro recess and protrusion structure, may utilize circularly polarized light, or may be a combination thereof. The configuration of the anti-reflection film 25 may be any configuration that can suppress the reflection of the light that is incident on the photoelectric conversion film 13.

The anti-reflection film 25 includes, for example, SiO₂, SiN, etc. The anti-reflection film 25 is, for example, insulative. Therefore, the anti-reflection film 25 is not provided between the second electrode 12 and the photoelectric conversion film 13. For example, the anti-reflection film 25 is provided on the portion (the portion on which the light is incident) of the photoelectric conversion film 13 exposed at the openings 12b. In the case where the anti-reflection film 25 is conductive, the anti-reflection film 25 may extend between the second electrode 12 and the photoelectric conversion film 13.

Thus, the anti-reflection film 25 is provided. Thereby, for example, compared to the case where there is no anti-reflection film 25, the photoelectric conversion efficiency can be increased further.

As in the solar cell 22 shown in FIG. 3B, the anti-reflection film 25 may be provided on the electrets 14. Thereby, the reflection of the light that is incident on the electrets 14 also can be suppressed. In the example, multiple anti-reflection films 25 are provided respectively on the electrets 14. In the case where the anti-reflection films 25 are provided on the electrets 14, the anti-reflection films 25 may extend on the second electrode 12. For example, one continuous anti-reflection film 25 may be provided on the second electrode 12 and the electrets 14.

### Third Embodiment

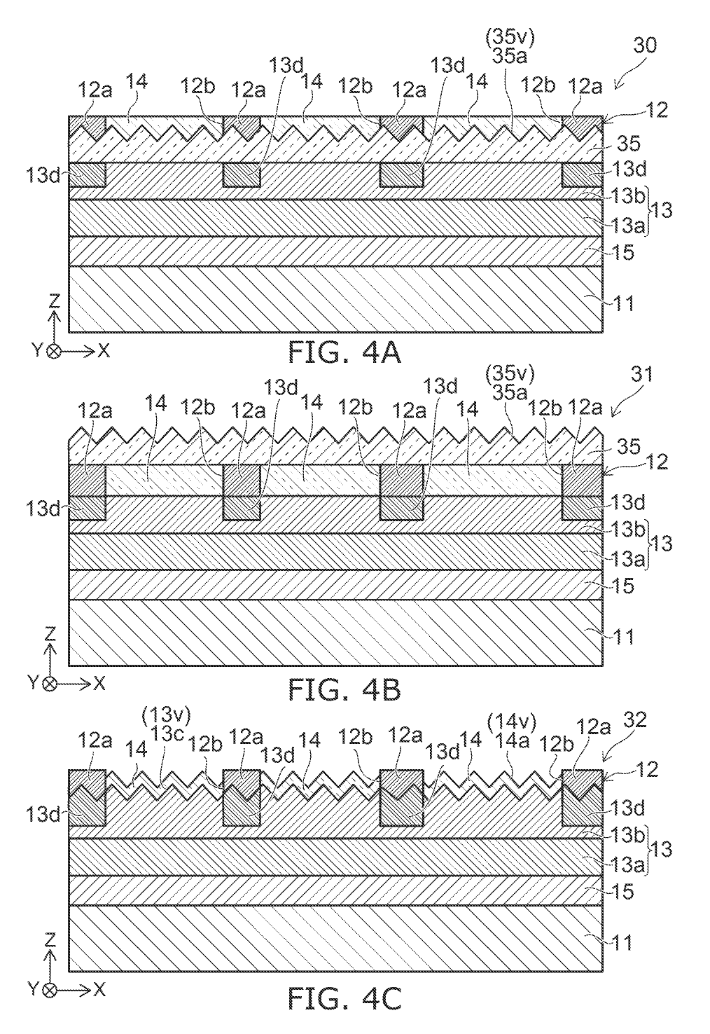

FIG. 4A to FIG. 4C are cross-sectional views schematically showing solar cells according to a third embodiment.

As shown in FIG. 4A, a solar cell 30 further includes an optical layer 35. The optical layer 35 is provided on the photoelectric conversion film 13. In the solar cell 30, the optical layer 35 is provided between the photoelectric conversion film 13 and the second electrode 12 and between the photoelectric conversion film 13 and the electrets 14. In other words, in the solar cell 30, the optical layer 35 is provided on the photoelectric conversion film 13; and the second electrode 12 and the electrets 14 are provided on the optical layer 35.

The optical layer 35 includes, for example, a material that is light-transmissive and conductive. The optical layer 35 may be insulative. In such a case, similarly to the anti-reflection film 25 shown in FIG. 3A, it is sufficient to provide the optical layer 35 only in the portion that transmits the light.

The optical layer 35 has an upper surface 35a. Multiple recesses and protrusions 35v are provided in the upper surface 35a. The recesses and protrusions 35v may have a periodic configuration or a random configuration. The size of the recesses and protrusions 35v is about slightly larger than the wavelength of the light. The size (the width and the height) of one recess and protrusion 35v is, for example, not less than 400 nm and not more than 1000 nm. The recesses and protrusions 35v are so-called texture.

The optical layer 35 changes the travel direction of the light that is incident on the upper surface 35a by the recesses and protrusions 35v. For example, the optical layer 35 causes the light that is incident on the photoelectric conversion film 13 to be tilted with respect to the film surface of the photoelectric conversion film 13. Thereby, the optical path length of the light that is incident on the photoelectric conversion film 13 (the depletion layer DL) lengthens; and the short circuit current can be increased. Accordingly, in the solar cell 30, the photoelectric conversion efficiency can be increased further by providing the optical layer 35.

In a solar cell 31 as shown in FIG. 4B, the optical layer 35 is provided on the second electrode 12 and the electret 14. Thus, the optical layer 35 may be provided between the photoelectric conversion film 13 and the electret 14 (the second electrode 12) or may be provided on the electret 14 (the second electrode 12).

In a solar cell 32 as shown in FIG. 4C, recesses and protrusions 13v are provided in an upper surface 13c of the photoelectric conversion film 13. Thus, the recesses and protrusions 13v may be provided in the upper surface 13c of the photoelectric conversion film 13 without providing the optical layer 35. In the solar cells 31 and 32 as well, similarly to the solar cell 30, the optical path length of the light that is incident on the photoelectric conversion film 13 is increased; and the photoelectric conversion efficiency can be increased.

In the solar cell 32, multiple recesses and protrusions 14v that correspond to the configuration of the recesses and protrusions 13v of the photoelectric conversion film 13 are provided in an upper surface 14a of the electret 14. Thereby, for example, the reflection of the light at the upper surface 14a of the electret 14 can be suppressed.

In the case where the electret 14 is provided on the optical layer 35 (the case of FIG. 4A), the multiple recesses and protrusions 14v that correspond to the configuration of the recesses and protrusions 35v of the optical layer 35 may be provided in the upper surface 14a of the electret 14.

### Fourth Embodiment

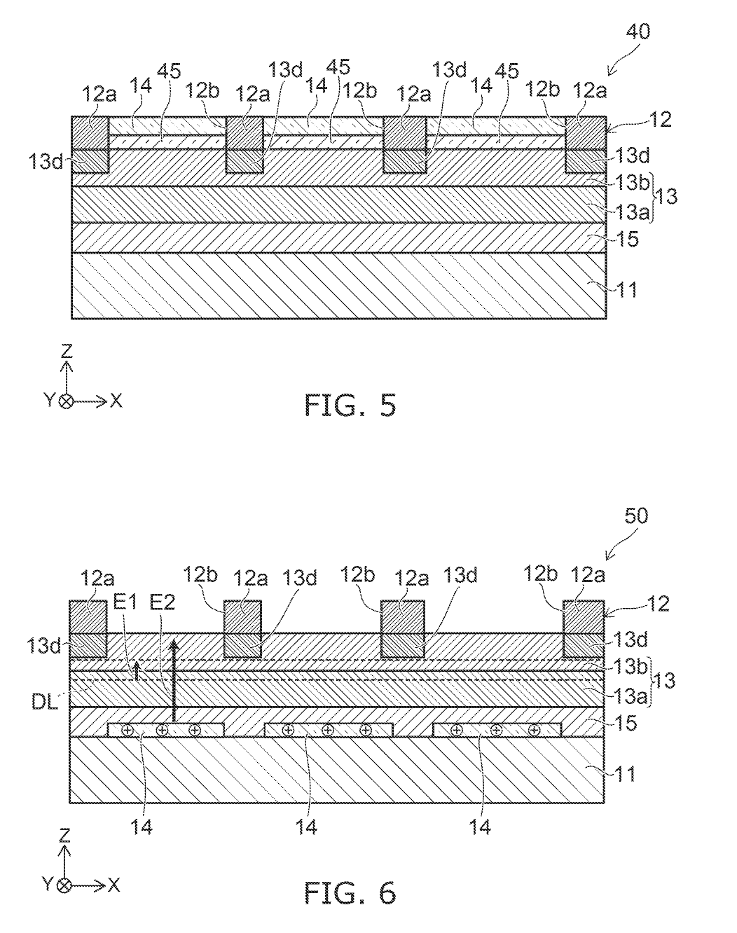

FIG. 5 is a cross-sectional view schematically showing a solar cell according to a fourth embodiment.

As shown in FIG. 5, the solar cell 40 further includes a protective layer 45. The protective layer 45 is provided on a portion of the photoelectric conversion film 13. For example, the protective layer 45 is provided between the photoelectric conversion film 13 and the electrets 14. In other words, the protective layer 45 is provided on the portion of the photoelectric conversion film 13 exposed at the openings 12b. In the example, the multiple protective layers 45 are provided respectively between the photoelectric conversion film 13 and the electrets 14.

The protective layer 45 is insulative. The protective layer 45 includes, for example, SiO₂, etc. Therefore, the second electrode 12 is provided on the portion of the photoelectric conversion film 13 not covered with the protective layer 45.

Thus, the protective layer 45 is provided. Thereby, for example, the recombination of the carriers in the portion of the photoelectric conversion film 13 not connected to the second electrode 12 (the portion where the second electrode 12 and the photoelectric conversion film 13 do not overlap in the Z-axis direction) can be suppressed. Thereby, in the solar cell 40, the photoelectric conversion efficiency can be increased further.

### Fifth Embodiment

FIG. 6 is a cross-sectional view schematically showing a solar cell according to a fifth embodiment.

In the solar cell 50 as shown in FIG. 6, the electrets 14 are provided between the first electrode 11 and the photoelectric conversion film 13. The electrets 14 are provided between the first electrode 11 and the conductive layer 15. The electrets 14 may be provided between the photoelectric conversion film 13 and the conductive layer 15. In the example, the multiple electrets 14 are provided at positions where the openings 12b and the multiple electrets 14 overlap in the Z-axis direction. In the case where the electrets 14 are provided between the first electrode 11 and the photoelectric conversion film 13, one electret 14 may be provided so that the one electret 14 and the conductive units 12a overlap in the Z-axis direction.

In the example, the polarity of the charge retained by the electrets 14 is the same as the polarity of the charge of the majority carrier of the second semiconductor layer 13b. In other words, the electrets 14 retain the same positive charge as the holes which are the majority carrier of the second semiconductor layer 13b. In other words, the electrets 14 are positively charged.

Thereby, the electrets 14 generate the external electric field E2 in the direction from the first electrode 11 toward the electrets 14. The electrets 14 generate the external electric field E2; and the external electric field E2 and the built-in electric field E1 are oriented toward the same side.

Accordingly, in the solar cell 50 according to the embodiment, similarly to the embodiments recited above, the depletion layer spreads similarly to the case where the reverse bias is applied without providing the external power supply; and the photoelectric conversion efficiency can be increased.

As the electrets 14 in the example, for example, a so-called alkaline-based electret is used in which positive ions such as K⁺, Na⁺, etc., of a solution including the positive ions are introduced to an oxide film of silicon, etc., by thermal oxidation, and the oxide film is made into an electret by heat treatment and bias processing. Thereby, the electrets 14 can retain positive charge. Thus, the electrets 14 may be positively charged.

In the case where the electrets 14 are provided between the first electrode 11 and the photoelectric conversion film 13, the electrets 14 are not necessarily light-transmissive. However, the electrets 14 are light-transmissive in the solar cell 50. Thereby, for example, the light that is reflected by the first electrode 11 can be incident again on the photoelectric conversion film 13. For example, the photoelectric conversion efficiency can be increased.

### Sixth Embodiment

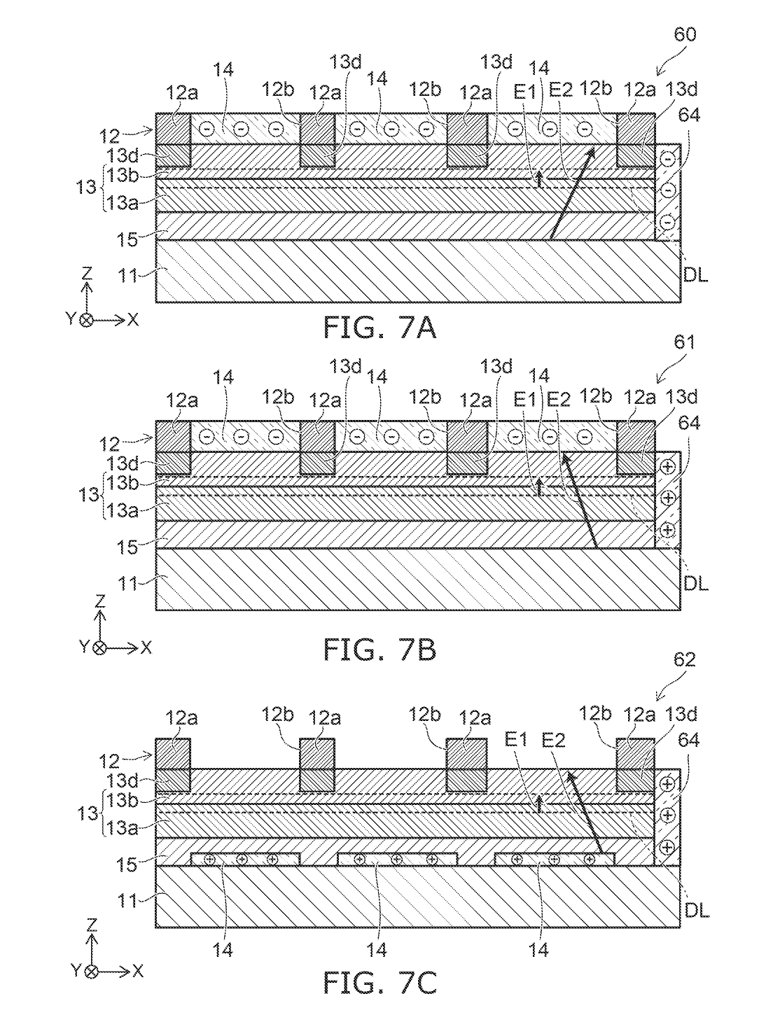

FIG. 7A to FIG. 7C are cross-sectional views schematically showing solar cells according to a sixth embodiment.

As shown in FIG. 7A, a solar cell 60 further includes an electret 64 (a second electret). The electret 64 is arranged with the photoelectric conversion film 13 in a direction perpendicular to the Z-axis direction. For example, the electret 64 is arranged with the photoelectric conversion film 13 in the X-axis direction. In other words, the electret 64 is arranged with the photoelectric conversion film 13 in the direction in which the conductive units 12a of the second electrode 12 are arranged. The direction in which the electret 64 is arranged is not limited to the X-axis direction and may be, for example, the Y-axis direction. The electret 64 may be arranged simultaneously in the X-axis and Y-axis directions; and the arrangement is not limited to the X-axis and Y-axis directions.

For example, the electret 64 retains a negative charge. The electret 64 causes the external electric field E2 to tilt with respect to the Z-axis direction (the direction in which the electrets 14 are arranged). The electret 64 causes the external electric field E2 to tilt in the X-axis direction (the direction in which the electret 64 is arranged).

Thereby, for example, the carriers that are generated in the depletion layer DL can be attracted easily by the conductive units 12a. For example, the recombination of the carriers in the portion of the photoelectric conversion film 13 not connected to the second electrode 12 can be suppressed. Thereby, in the solar cell 60, the current is extracted easily; and the photoelectric conversion efficiency can be increased further.

For example, the absolute value of the charge density of the electret 64 is less than the absolute value of the charge density of the electrets 14. Thereby, the undesirable orientation of the external electric field E2 toward the X-axis direction can be suppressed. It is sufficient for the charge density of the electret 64 to be set so that the Z-axis direction component of the external electric field E2 does not become too small.

The electret 64 may be multiply provided. For example, multiple electrets 64 may be disposed around the photoelectric conversion film 13 using the Z-axis direction as an axis. The electret 64 may have an annular configuration around the photoelectric conversion film 13 using the Z-axis direction as an axis.

As in a solar cell 61 shown in FIG. 7B, the electret 64 may retain a positive charge. The electret 64 may be resin-based or alkaline-based. In the case where multiple electrets 64 are provided, for example, an electret 64 that retains a positive charge may be provided at one X-axis direction side of the photoelectric conversion film 13; and an electret 64 that retains a negative charge may be provided at the other X-axis direction side of the photoelectric conversion film 13.

As shown in FIG. 7C, the electret 64 may be provided in a solar cell 62 in which the electrets 14 are provided between the first electrode 11 and the photoelectric conversion film 13. In such a case as well, the charge that is retained by the electret 64 may be positive or negative.

### Seventh Embodiment

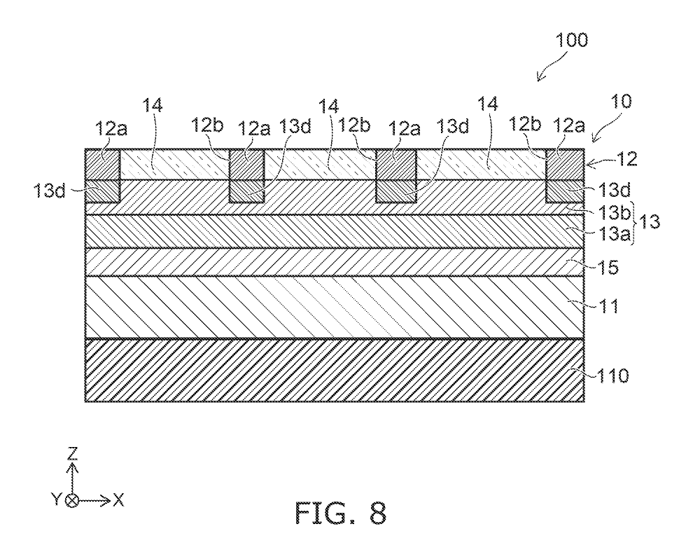

FIG. 8 is a cross-sectional view schematically showing a solar cell film according to a seventh embodiment.

As shown in FIG. 8, the solar cell film 100 includes a substrate 110 that is flexible, and the solar cell 10 that is provided on the substrate 110. The substrate 110 includes, for example, a resin material. For example, the first electrode 11, the second electrode 12, the photoelectric conversion film 13, the electrets 14, and the conductive layer 15 are formed in a thin-film configuration. Thereby, the solar cell 10 can be flexible. In other words, the solar cell film 100 can be flexible.

Thus, the solar cell 10 may be used in the solar cell film 100 that is flexible. Although the solar cell 10 described in the first embodiment is used in the solar cell film 100 in the example, the solar cell that is used in the solar cell film 100 may be any of the solar cells 20, 22, 30 to 32, 40, 50, and 60 to 62 described in the embodiments recited above.

### Eighth Embodiment

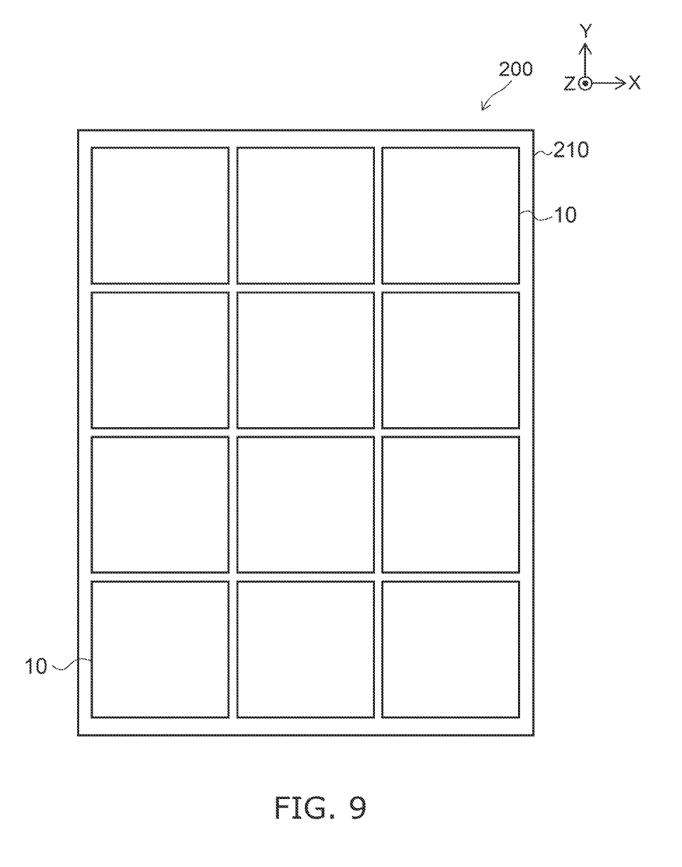

FIG. 9 is a plan view schematically showing a solar cell panel according to an eighth embodiment.

As shown in FIG. 9, the solar cell panel 200 includes a substrate 210, and the multiple solar cells 10 that are arranged on the substrate 210. In the example, the solar cell panel 200 includes an arrangement of three solar cells 10 in the X-axis direction and four solar cells 10 in the Y-axis direction for a total of twelve solar cells 10. The length of one side of the solar cell 10 is about 30 cm. The size of the solar cell panel 200 is, for example, about 1 m by 1.2 m. The multiple solar cells 10 are connected in series or in parallel. The solar cells 10 are electrically connected to each other. Thereby, the solar cell panel 200 outputs a prescribed voltage and current.

Thus, the solar cell 10 may be used in the solar cell panel 200 in which the multiple solar cells 10 are electrically connected. The number and arrangement of solar cells 10 included in the solar cell panel 200 may be set arbitrarily. The planar configuration of each solar cell 10 is not limited to a rectangular configuration and may be any configuration. The solar cell that is used in the solar cell panel 200 may be any of the solar cells 10, 20, 22, 30 to 32, 40, 50, and 60 to 62 described in the embodiments recited above.

According to the embodiments, a solar cell, a solar cell panel, and a solar cell film are provided in which the photoelectric conversion efficiency is increased.

In the specification of the application, “perpendicular” and “parallel” include not only strictly perpendicular and strictly parallel but also, for example, the fluctuation due to manufacturing processes, etc.; and it is sufficient to be substantially perpendicular and substantially parallel. In the specification of the application, the state of being “provided on” includes not only the state of being provided in direct contact but also the state of being provided with another component inserted therebetween. The state of being “stacked” includes not only the state of overlapping in contact with each other but also the state of overlapping with another component inserted therebetween. The state of being “opposed” includes not only the state of directly facing each other but also the state of facing each other with another component inserted therebetween.

Hereinabove, embodiments of the invention are described with reference to specific examples.

However, the embodiments of the invention are not limited to these specific examples. For example, one skilled in the art may similarly practice the invention by appropriately selecting specific configurations of components included in the solar cell, the solar cell panel, and the solar cell film such as the first electrode, the second electrode, the photoelectric conversion film, the first semiconductor layer, the second semiconductor layer, the first electret, the second electret, the anti-reflection film, the optical layer, the protective layer, the substrate, etc., from known art; and such practice is within the scope of the invention to the extent that similar effects can be obtained.

Further, any two or more components of the specific examples may be combined within the extent of technical feasibility and are within the scope of the invention to the extent that the spirit of the invention is included.

Moreover, all solar cells, solar cell panels, and solar cell films practicable by an appropriate design modification by one skilled in the art based on the solar cells, the solar cell panels, and the solar cell films described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A solar cell, comprising:
a first electrode;
a photoelectric conversion film provided on the first electrode, the photoelectric conversion film including a first semiconductor layer and a second semiconductor layer, the first semiconductor layer being of a first conductivity type, the second semiconductor layer being of a second conductivity type and provided on the first semiconductor layer, the first semiconductor layer and the second semiconductor layer generating a built-in electric field;
a second electrode provided on the photoelectric conversion film; and
a first electret arranged with the photoelectric conversion film in a stacking direction of the first semiconductor layer and the second semiconductor layer, the first electret generating an external electric field, the external electric field and the built-in electric field being oriented toward the same side.

2. The solar cell according to claim 1, wherein
the first electret is light-transmissive and provided on the photoelectric conversion film, and
a polarity of a charge retained by the first electret is the same as a polarity of a charge of a majority carrier of the first semiconductor layer.

3. The solar cell according to claim 2, wherein
the second electrode includes a plurality of conductive units,
the conductive units extends in a first direction and is arranged in a second direction, the first direction being perpendicular to the stacking direction, the second direction being perpendicular to the stacking direction and the first direction, and
the first electret is provided between the conductive units.

4. The solar cell according to claim 1, wherein
the first electret is provided between the first electrode and the photoelectric conversion film, and
a polarity of a charge retained by the first electret is the same as a polarity of a charge of a majority carrier of the second semiconductor layer.

5. The solar cell according to claim 1, further comprising a second electret arranged with the photoelectric conversion film in a direction perpendicular to the stacking direction.

6. The solar cell according to claim 5, wherein an absolute value of a charge density of the second electret is less than an absolute value of a charge density of the first electret.

7. The solar cell according to claim 1, wherein the photoelectric conversion film is silicon-based or compound-based.

8. The solar cell according to claim 1, further comprising an anti-reflection film provided on the photoelectric conversion film.

9. The solar cell according to claim 8, wherein
the first electret is light-transmissive and provided on the photoelectric conversion film, and
the anti-reflection film is provided between the photoelectric conversion film and the first electret.

10. The solar cell according to claim 8, wherein
the first electret is light-transmissive and provided on the photoelectric conversion film, and
the anti-reflection film is provided on the first electret.

11. The solar cell according to claim 1, further comprising an optical layer provided on the photoelectric conversion film,
the optical layer including an upper surface, the upper surface including a recess and a protrusion.

12. The solar cell according to claim 11, wherein
the first electret is light-transmissive and provided on the photoelectric conversion film, and
the optical layer is provided between the photoelectric conversion film and the second electrode and between the photoelectric conversion film and the first electret.

13. The solar cell according to claim 11, wherein
the first electret is light-transmissive and provided on the photoelectric conversion film, and
the optical layer is provided on the second electrode and on the first electret.

14. The solar cell according to claim 1, wherein the first electret is light-transmissive, is provided on the photoelectric conversion film, and includes an upper surface, the upper surface includes a recess and a protrusion.

15. The solar cell according to claim 1, further comprising a protective layer provided on a portion of the photoelectric conversion film, the protective layer being insulative,
the second electrode being provided on a portion of the photoelectric conversion film not covered with the protective layer.

16. The solar cell according to claim 15, wherein
the first electret is light-transmissive and provided on the photoelectric conversion film, and
the protective layer is provided between the photoelectric conversion film and the first electret.

17. The solar cell according to claim 1, wherein
the second semiconductor layer includes a first region and a second region, the first region overlapping the second electrode in the stacking direction, the second region not overlapping the second electrode in the stacking direction, and
a concentration of an impurity included in the first region is higher than a concentration of an impurity included in the second region.

18. The solar cell according to claim 1, wherein the first electrode is light-reflective.

19. A solar cell panel, comprising:
a substrate;
a plurality of solar cells electrically connected to each other and arranged on the substrate,
each of the solar cells including
a first electrode,
a photoelectric conversion film provided on the first electrode, the photoelectric conversion film including a first semiconductor layer and a second semiconductor layer, the first semiconductor layer being of a first conductivity type, the second semiconductor layer being of a second conductivity type and provided on the first semiconductor layer, the first semiconductor layer and the second semiconductor layer generating a built-in electric field,
a second electrode provided on the photoelectric conversion film, and
a first electret arranged with the photoelectric conversion film in a stacking direction of the first semiconductor layer and the second semiconductor layer, the first electret generating an external electric field, the external electric field and the built-in electric field being oriented toward the same side.

20. A solar cell film, comprising:
a substrate, the substrate being flexible; and
a solar cell provided on the substrate, the solar cell including
a first electrode,
a photoelectric conversion film provided on the first electrode, the photoelectric conversion film including a first semiconductor layer and a second semiconductor layer, the first semiconductor layer being of a first conductivity type, the second semiconductor layer being of a second conductivity type and provided on the first semiconductor layer, the first semiconductor layer and the second semiconductor layer generating a built-in electric field,
a second electrode provided on the photoelectric conversion film,
a first electret arranged with the photoelectric conversion film in a stacking direction of the first semiconductor layer and the second semiconductor layer, the first electret generating an external electric field, the external electric field and the built-in electric field being oriented toward the same side.
